(19) United States
(12) Patent Application Publication
(10) Pub. No.: US 2016/0351398 A1
(43) Pub. Date: Dec. 1, 2016

(54) SEMICONDUCTOR ELEMENT MANUFACTURING METHOD

(71) Applicant: TOKYO ELECTRON LIMITED, Tokyo (JP)

(72) Inventors: Hirokazu UEDA, Yamanashi (JP); Hidenori MIYOSHI, Miyagi (JP); Masahiro OKA, Yamanashi (JP); Genji NAKAMURA, Yamanashi (JP); Yuki KOBAYASHI, Miyagi (JP); Yasuhiro SUGIMOTO, Yamanashi (JP)

(73) Assignee: TOKYO ELECTRON LIMITED, Tokyo (JP)

(21) Appl. No.: 15/165,085

(22) Filed: May 26, 2016

(30) Foreign Application Priority Data
May 27, 2015 (JP) 2015-107555

(51) Int. Cl. H01L 21/223; H01L 21/324; H01J 37/32; H01L 21/265

(52) U.S. Cl. CPC H01L 21/2236; H01L 21/265; H01L 21/324; H01J 37/32449; H01J 37/32412; H01J 37/32201; H01J 2237/3365

(57) ABSTRACT

Disclosed is a method of manufacturing a semiconductor element by implanting a dopant to a substrate to be processed. High frequency plasma is generated within a processing container by using microwaves. By using the generated high frequency plasma, a plasma doping treatment is performed on a germanium-containing to-be-processed substrate which is held on a holding table within the processing container.

### CROSS-REFERENCE TO RELATED APPLICATIONS

This application is based on and claims priority from Japanese Patent Application No. 2015-107555, filed on May 27, 2015, with the Japan Patent Office, the disclosure of which is incorporated herein in its entirety by reference.

### TECHNICAL FIELD

The present disclosure relates to a semiconductor element manufacturing method.

### BACKGROUND

Semiconductor elements such as, for example, a large scale integrated circuit (LSI) and a metal oxide semiconductor (MOS) transistor, are manufactured by performing processings such as, for example, doping, etching, chemical vapor deposition (CVD), and sputtering, on a semiconductor substrate (wafer) as a substrate to be processed.

Here, doping methods include an ion doping method that is performed by using an ion implanting apparatus, and a plasma doping method that implants radicals or ions of a dopant to a surface of an object to be processed (hereinafter, referred to as “to-be-processed substrate”) by directly using plasma. In addition, with respect to a doping target object which has a three-dimensional structure such as, for example, a fin field effect transistor (FinFET) type semiconductor element, as a method of implanting a dopant impurity uniformly regardless of an irregularity area of the three-dimensional structure (conformal doping) has recently been requested very strongly, a plurality of doping methods using plasma have been tried and reported.

Meanwhile, in recent, miniaturization and high speed performance using a silicon substrate have almost reached their limits. Accordingly, it has been actively attempted to use a material, which is superior to silicon in electrical characteristic, as a to-be-processed substrate, instead of silicon. For example, germanium (Ge) or Groups III-V (e.g., indium (In)) having higher carrier mobility than silicon is reviewed for use as a substrate material of a semiconductor element.

See, for example, the following documents.
Document 1: K. Han*, S. Tang, T. Rockwell, L. Godet, H. Persing, C. Campbell, S. Salimian, Junction Technology (IWJT), 2012 12th International Workshop on, Date 14-15 May 2012, IEEE
Document 2: Y. Sasaki, L. Godetl, T. Chiarella, D. P. Brunco2, T. Rockwell1, J. W. Lee, B. Colombeaul, M. Togo, S. A. Chew, G. Zschaetszch, K. B. Noh3, A. De Keersgieter, G. Boccardi, M. S. Kim, G. Hellings, P. Martin1, W. Vandervorst, A. Thean, and N. Horiguchi, “Improved Sidewall Doping of Extensions by AsH₃ Ion Assisted Deposition and Doping (IADD) with Small Implant Angle for Scaled NMOS Si Bulk FinFETs,” proceeding IEDM 2013, IEEE
Document 3: Janssens et al., IVST B24, 510 (2006)
Document 4: Impellizzeri et al., J. Appl. Phys. 106, 013518 (2009)
Document 5: H. Ueda, P. L. G. Ventzek, M. Oka, M. Horigome, Y. Kobayashi, Y. Sugimoto, T. Nozawa, and S. Kawakami, “Conformal doping of topographic silicon structures using a radial line slot antenna plasma source” J. Appl. Phys. 115, 214904 (2014)
Document 6: H. Miyoshi et al., JJAP 53 (2014) 04EA05
Document 7: S. Brotzmann et al., JAP 103 (2008), 033508
Document 8: C. O. Chui et al., APL 83 (2003) p. 3275

### SUMMARY

In an aspect, the semiconductor element manufacturing method of the present disclosure is a method of manufacturing a semiconductor element by implanting a dopant to a to-be-processed substrate. The method includes a plasma doping treatment step of performing a plasma doping treatment on a germanium-containing to-be-processed substrate which is held on a holding table within a processing container, by generating high frequency plasma within the processing container by using microwaves.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating a main portion of a doping apparatus according to a first exemplary embodiment.

FIG. 2 is a schematic view of a slot antenna plate included in the doping apparatus illustrated in FIG. 1 when viewed in the direction of arrow III in FIG. 1.

FIG. 3 is a flowchart illustrating an exemplary treatment flow of a semiconductor element manufacturing method according to the first exemplary embodiment.

FIG. 4 is a view illustrating an exemplary secondary ion mass spectrometry (SIMS) profile obtained when arsenic is doped on a germanium substrate by using the semiconductor element manufacturing method according to the first exemplary embodiment.

FIG. 5 is a view obtained by plotting a diffusion coefficient of a dopant with respect to an annealing temperature in the case of using the semiconductor element manufacturing method according to the first exemplary embodiment.

FIG. 6 is a view illustrating a result obtained by verifying a sheet resistance value for an annealing temperature through a 4-point probe method or a Hall effect measurement method in the case of performing an annealing treatment by using the semiconductor element manufacturing method according to the first exemplary embodiment.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

As described in Document 3, in the case where, for example, germanium is used as a to-be-processed substrate, severe surface roughness occurs when ion implantation or annealing is performed under a treatment condition that is the same as that conventionally performed for a silicon substrate. Accordingly, when a treatment that is the same as that conventionally used for a silicon substrate is applied to germanium or Groups III-V, a product having a smooth surface cannot be manufactured.

Thus, as described in Document 4, a technique of depositing a silicon dioxide on a germanium substrate or a technique of cooling a wafer with liquid nitrogen at the time of ion implantation has been suggested in order to suppress the surface roughness.

However, these methods impose a large constraint in constructing processes (steps) and may cause another problem when the methods are adaptively applied. For example, the method of depositing a silicon dioxide on a germanium substrate as described in Document 4 may not be used when it is desired to shallowly implant an element to a germanium substrate. In addition, since the method of cooling a wafer with liquid nitrogen at the time of ion implantation requires, for example, a measure against dew condensation of a wafer surface, it is not easy to construct a facility which is capable of performing ion implantation while cooling a wafer substrate material, for a large-scale integration (LSI) manufacturing process.

In addition, it is known that an activation concentration of an n-type impurity within the to-be-processed substrate is reduced when germanium is used as a to-be-processed substrate. An inactivation of impurity is predominant, particularly, in an n-type impurity. Even in the case of a p-type impurity, an impurity loss also occurs near a substrate surface.

In addition, as in the case where a silicon substrate is used, it is also difficult to implement a conformal doping for a FinFET type semiconductor element having a three-dimensional structure when germanium is used as a to-be-processed substrate. This is described in detail in Non-Patent Document 5.

A plasma doping using microwaves according to an exemplary embodiment which is described hereinafter suggests a totally new principle of implanting a dopant to a processing target sample with respect to a method using a different dopant implanting principle, i.e., a method of implanting an ionized dopant.

The plasma doping according to the present exemplary embodiment actively uses low energy ions (1 eV to 2 eV) or radical components of a dopant under a high pressure condition (100 mTorr or higher). Compared to a method using, for example, inductively coupled plasma (ICP), microwave plasma may reduce the electron temperature in plasma which can be generated under an identical pressure condition, to about half. Further, the microwave plasma may generate electrons densely in plasma. Hence, a plasma doping treatment is enabled under the high pressure condition described above. On the contrary, in other plasma sources (e.g., ICP), a low pressure (100 mTorr or less) is necessarily selected in order to suppress a damage to a to-be-processed substrate. Further, it has been believed that in this condition, it is impossible to implant, especially, an element having a large mass (e.g., arsenic) to a substrate having irregularities with a reduced damage.

The exemplary embodiment described hereinafter enables implanting even an element having a large mass (e.g., arsenic) to a substrate having irregularities with a reduced damage by using a plasma doping using microwaves. Further, a conformal doping is achieved even for a substrate with irregularities by performing two-step annealing.

### First Exemplary Embodiment

A semiconductor element manufacturing method according to a first exemplary embodiment is a method of manufacturing a semiconductor element by implanting a dopant to a to-be-processed substrate and includes a plasma doping treatment step of performing a plasma doping treatment on a to-be-processed substrate which contains germanium and is held on a holding table within a processing container, by generating high frequency plasma within the processing container by using microwaves.

In the semiconductor element manufacturing method according to the first exemplary embodiment, the plasma doping treatment step generates surface wave plasma as the high frequency plasma.

The semiconductor element manufacturing method according to the first exemplary embodiment further includes an annealing treatment step of performing an annealing treatment on the to-be-processed substrate that has been subjected to the plasma doping treatment.

The semiconductor element manufacturing method according to the first exemplary embodiment performs an intermediate annealing treatment, and then, performs an activation annealing treatment to activate impurity within the to-be-processed substrate, in the annealing treatment step.

In the semiconductor element manufacturing method according to the first exemplary embodiment, the intermediate annealing treatment is performed at a temperature in a range of 300° C. to 650° C.

In the semiconductor element manufacturing method according to the first exemplary embodiment, the activation annealing treatment is performed at a temperature in a range of about 650° C. to 800° C.

In the semiconductor element manufacturing method according to the first exemplary embodiment, a plasma doping is performed on the substrate. For example, in the semiconductor element manufacturing method according to the first exemplary embodiment, a doping apparatus generates high frequency plasma by using microwaves. In addition, for example, in the semiconductor element manufacturing method according to the first exemplary embodiment, the doping apparatus generates surface wave plasma using microwaves. In addition, for example, in the semiconductor element manufacturing method according to the first exemplary embodiment, the doping apparatus implants a predetermined dopant to a germanium-containing substrate by a plasma doping. By using the plasma doping which causes a less damage to a substrate, it may be possible to suppress surface roughness of a substrate containing germanium that easily suffers from surface roughness.

In the first exemplary embodiment, a germanium-containing substrate is used as the to-be-processed substrate. For example, a silicon germanium (SiGe) substrate is used. In addition, other materials which easily suffer from surface roughness in a conventional method of, for example, implanting ions may be also used. For example, materials such as, for example, Groups III-V semiconductors may be used. As Group III elements, for example, aluminum (Al), gallium (Ga), and indium (In) may be exemplified. As Group V elements, for example, nitrogen (N), phosphorous (P), arsenic (As), and antimony (Sb) may be exemplified. As Group III-V semiconductors, for example, gallium arsenide (GaAs), indium phosphide (InP), and gallium nitride (GaN) may be exemplified.

In the semiconductor element manufacturing method according to the first exemplary embodiment, a conformal doping is implemented by performing a two-step annealing treatment on a to-be-processed substrate after performing the plasma doping. In the two-step annealing treatment, an intermediate annealing treatment is performed to implement the conformal doping, and thereafter, an activation annealing treatment aimed to activate a doped impurity is separately performed. Details of the two-step annealing treatment will be described later.

According to an aspect of the present disclosure, the semiconductor element manufacturing method exhibits an effect on manufacturing a semiconductor element which accompanies a high quality PN junction even when germanium or Groups III-V is contained in a to-be-processed substrate.

(Doping Apparatus According to First Exemplary Embodiment)

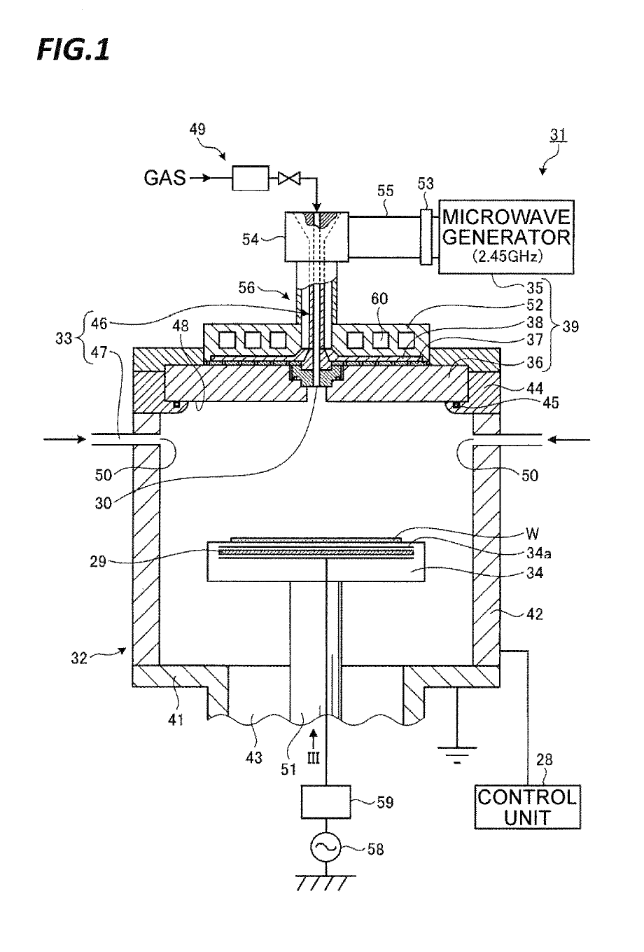

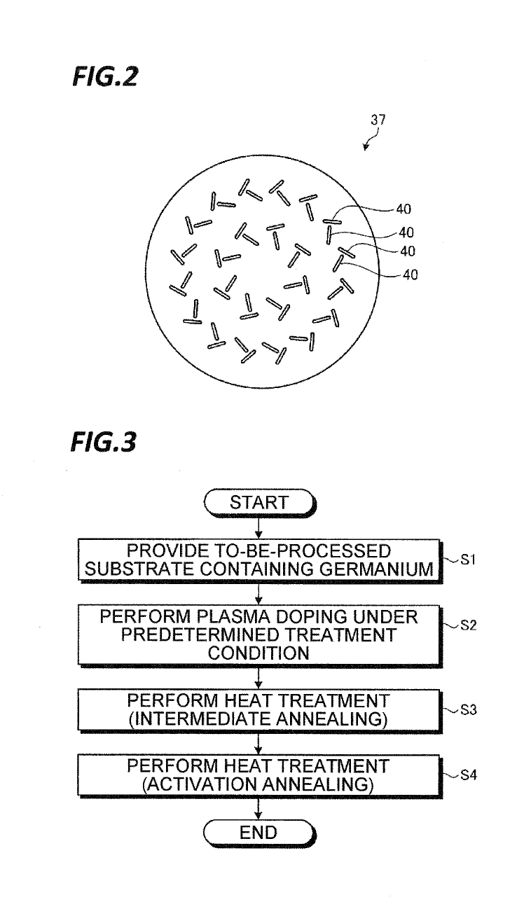

FIG. 1 is a schematic cross-sectional view illustrating a principle part of a doping apparatus according to a first exemplary embodiment. FIG. 2 is a view of a slot antenna plate included in the doping apparatus illustrated in FIG. 1 when viewed from the lower side, i.e., in the direction of arrow III in FIG. 1. Meanwhile, in FIG. 1, hatching is omitted for some components for easy understanding. In this exemplary embodiment, the vertical direction in the paper of FIG. 1 corresponds to the vertical direction of the doping apparatus.

Referring to FIGS. 1 and 2, the doping apparatus 31 includes a processing container 32 within which doping is performed on a to-be-processed substrate W, a gas supply section 33 that supplies a plasma excitation gas or a doping gas to the inside of the processing container 32, a disc-shaped holding table 34 that holds the to-be-processed substrate W thereon, a plasma generation mechanism that generates plasma within the processing container 32 using microwaves, a pressure adjustment mechanism that adjusts the pressure within the processing container 32, a bias power supply mechanism that supplies an AC (alternating current) bias power to the holding table 34, and a controller 28 that controls operations of the entire doping apparatus 31. The controller 28 controls various parameters of the entire doping apparatus 31, such as, for example, the gas flow rate in the gas supply unit 33, the pressure within the processing container 32, and the bias power supplied to the holding plate 34.

The processing container 32 includes a bottom portion 41 positioned below the holding table 34 and a side wall 42 extending upwardly from the outer periphery of the bottom portion 41. The side wall 42 has a substantially cylindrical shape. In the bottom portion 41 of the processing container 32, an exhaust port 43 for exhausting gas is provided to penetrate through a portion of the bottom portion 41. The top side of the processing container 32 is opened, and the processing container 32 is configured to be sealed by a cover unit 44 placed on the top side of the processing container 32, a dielectric window 36 to be described later, and an O ring 45 as a seal member interposed between the dielectric window 36 and the cover unit 44.

The gas supply section 33 includes a first gas supply section 46 that ejects a gas toward the center of the to-be-processed substrate W, and a second gas supply section 47 that ejects a gas from the outside of the to-be-processed substrate W. A gas supply hole 30 that supplies a gas in the first gas supply section 46 is provided at the center in the diametric direction of the dielectric window 36 and at a position retreated to the inner side of the dielectric window 36 from the bottom surface 48 of the dielectric window 36 which becomes an opposite surface to the holding table 34. The first gas supply section 46 supplies an inert gas for plasma excitation or a doping gas while adjusting, for example, a flow rate by a gas supply system 49 connected to the first gas supply section 46. The second gas supply section 47 is formed by providing a plurality of gas supply holes 50 that supply the inert gas for plasma excitation or the doping gas to the inside of the processing container 32 in a portion of the upper side of the side wall 42. The plurality of gas supply holes 50 are provided in the circumferential direction at regular intervals. The first gas supply section 46 and the second gas supply section 47 are supplied with the same kind of inert gas for plasma excitation or doping gas from the same gas supply sources. In addition, according to a request, a control content, or the like, separate gases may be supplied from the first gas supply section 46 and the second gas supply section 47, and for example, the flow rate ratio of the separate gases may be adjusted.

In the holding table 34, a high frequency power supply 58 for radio frequency (RF) bias is electrically connected to an electrode within the holding table 34 through a matching unit 59. The high frequency power supply 58 is capable of outputting high frequency waves of, for example, 13.56 MHz at a predetermined power (bias power). The matching unit 59 accommodates a matcher that matches an impedance of the high frequency power supply 58 side with a load side impedance mainly of, the electrode, plasma, and the processing container 32, and a blocking condenser for self-bias generation is contained within the matcher. In addition, during the doping, the supply of the bias voltage to the holding table 34 properly varies as needed. The controller 28 controls the AC bias power supplied to the holding table 34, as a bias power supply mechanism.

The holding table 34 is capable of holding the to-be-processed substrate W thereon by an electrostatic chuck (not illustrated). Further, the holding table 34 includes, for example, a heater 34a for a temperature control and may be set to a desired temperature by a temperature control mechanism 29 provided inside the holding table 34. The holding table 34 is supported on an insulative cylindrical support 51 that extends vertically upward from the lower side of the bottom portion 41. The exhaust port 43 is provided through a portion of the bottom portion 41 of the processing container 32 along the outer circumference of the cylindrical support 51. An exhaust apparatus (not illustrated) is connected to the lower side of the annular exhaust port 43 through an exhaust pipe (not illustrated). The exhaust apparatus includes a vacuum pump such as, for example, a turbo molecular pump. By the exhaust apparatus, the inside of the processing container 32 may be decompressed to a predetermined pressure. The controller 28 adjusts the pressure within the processing container 32 by, for example, controlling the exhaust by the exhaust apparatus, as a pressure adjustment mechanism.

The plasma generation mechanism 39 includes a microwave generator 35 that is provided outside the processing container 32 and that generates microwaves for plasma excitation. In addition, the plasma generation mechanism 39 includes a dielectric window 36 that is arranged at a position opposite to the holding table 34 and introduces the microwaves generated by the microwave generator 35 into the processing container 32. In addition, the plasma generation mechanism 39 includes a slot antenna plate 37 that is provided with a plurality of slots 40, is placed above the dielectric window 36, and radiates microwaves to the dielectric window 36. In addition, the plasma generation mechanism 39 includes a dielectric member 38 that is placed above the slot antenna plate 37 and propagates the microwaves introduced from a coaxial waveguide 56 to be described later in a diametric direction.

The microwave generator 35 with a matching element 53 is connected to the upper portion of the coaxial waveguide 56 that introduces microwaves through a mode converter 54 and a waveguide 55. For example, microwaves of a TE mode generated from the microwave generator 35 pass through the waveguide 55, and are converted into a TEM mode by the mode converter 54 and propagated from the coaxial waveguide 56. As the frequency of the microwaves generated in the microwave generator 35, for example, 2.45 GHz is selected.

The dielectric window 36 has substantially a disc shape and is formed of a dielectric material. As a specific material of the dielectric window 36, for example, quartz or aluminum may be exemplified.

The slot antenna plate 37 has a thin disc shape. With respect to the plurality of slot holes 40, as illustrated in FIG. 2, two slot holes 40, which are orthogonal to each other with a predetermined interval, form one pair, and a plurality of pairs of slot holes 40 are arranged in the circumferential direction at predetermined intervals. The plurality of pairs of slot holes 4 are also arranged in the diametrical direction at predetermined intervals. Here, the slot antenna plate 37 may be a radial line slot antenna.

The microwaves generated by the microwave generator 35 are propagated through the coaxial waveguide 56. The microwaves are diffused radially outwardly in the region interposed between a cooling jacket 52 and the slot antenna plate 37, and radiated to the dielectric window 36 from the plurality of slot holes 40 formed in the slot antenna plate 37. The cooling jacket 52 includes a circulation path 60 that circulates a coolant therein to adjust the temperature of, for example, the dielectric member 38. The microwaves, which have penetrated the dielectric window 36, generate an electric field just below the dielectric window 36, thereby generating plasma within the processing container 32.

As described above, the plasma generation mechanism includes the dielectric window 36 provided at a position where the dielectric window is exposed within the processing container 32 and is opposite to the holding table 34. Here, the shortest distance between the dielectric window 36 and the to-be-processed substrate W held on the holding table 34 is set to be in a range of 5.5 cm to 15 cm.

In the case where microwave plasma is generated in the doping apparatus 31, a so-called plasma generation region, in which the electron temperature of plasma is relatively high, is formed just below the bottom surface 48 of the dielectric window 36, more specifically in the region positioned below about several cm from the bottom surface 48 of the dielectric window 36. In addition, in the region positioned vertically downward therefrom, a so-called plasma diffusion region is formed in which the plasma generated in the plasma generation region is diffused. The plasma diffusion region is a region in which the electron temperature of plasma is relatively low, and a plasma doping treatment, i.e., doping is performed in the plasma diffusion region. In addition, in the case where microwave plasma is generated in the doping apparatus 31, the electron density of plasma gets relatively higher. As such, so-called plasma damage is not caused to the to-be-processed substrate W at the time of doping, and due to the high electron density of plasma, efficient doping, more specifically, for example, a reduction of doping time may be achieved.

Here, for example, in inductively coupled plasma (ICP) of a general plasma source, since the generated amount of high energy ions is very largely increased compared to radicals and low energy ion components in the plasma, plasma irradiation damage to the to-be-processed substrate is also increased. On the contrary, by using the microwave plasma, efficient generation of radicals and low energy ion components is enabled in a high pressure zone where the pressure is 100 mTorr or higher. In addition, by using the microwave plasma, radicals (active species) are not affected by the plasma electric field. That is, since the plasma is electrically neutral, plasma irradiation damage to the to-be-processed substrate may be overwhelmingly alleviated compared to ions.

(Exemplary Treatment Flow of Semiconductor Element Manufacturing Method According to First Exemplary Embodiment)

Next, descriptions will be made on a method for manufacturing a semiconductor element by using a to-be-processed substrate W by means of the above-described doping apparatus. FIG. 3 is a flowchart illustrating an exemplary treatment flow of the semiconductor element manufacturing method according to the first exemplary embodiment.

As illustrated in FIG. 3, in the semiconductor element manufacturing method according to the first exemplary embodiment, a to-be-processed substrate W containing germanium is first provided (step S1). Then, the to-be-processed substrate W is carried into the processing container 32 and held on the holding table 34. As an example of the to-be-processed substrate W containing germanium, the above-mentioned silicon germanium (SiGe) substrate may be exemplified.

Next, plasma doping is performed under a predetermined condition (step S2). That is, a plasma doping treatment is performed by supplying a doping gas (a processing gas) into the processing container 32. That is, plasma (e.g., surface wave plasma) is generated within the processing container 32 using microwaves so as to perform a plasma doping treatment step in which a plasma doping treatment is performed on the to-be-processed substrate W held on the holding table 34 within the processing container 32. More specifically, the controller 28 causes radicals and low energy ion components to be generated through the radial line slot antenna such that the to-be-processed substrate W is doped.

An exemplary treatment condition is described below for a case in which plasma doping is performed on a to-be-processed substrate W containing germanium by using arsenic (As) as a dopant.

Doping apparatus: Microwave plasma doping apparatus

Microwave power: 5 kW/cm²

Pressure: 230 mTorr

RF bias: 300 W

Processing gas: AsH₃ (0.7%)/He diluted gas

Processing gas flow rate: 343 sccm (total gas flow rate 1,000 sccm)

H₂ flow rate: 5 sccm

Doping time: 100 sec

Meanwhile, since the RF bias (13.56 MHz) is applied for the purpose of further stabilizing plasma, the application of the RF bias to the stage is not an essential requirement. Assuming that the total flow rate of the processing gas is 1,000 sccm, the controller 28 allows AsH₃ (0.7%)/He diluted gas to flow at a flow rate of 343 sccm and uses He gas as the remainder of the processing gas. The controller 28 may add H₂ gas. Since the addition of the H₂ gas is aimed to improve the uniformity of the plasma generation, the addition is not an essential requirement in the semiconductor element manufacturing method of the present exemplary embodiment. Meanwhile, the treatment condition for performing the plasma doping is not limited to the above-described condition.

It is known that when plasma is generated by using microwaves, the plasma processing can be performed on a to-be-processed sample (wafer) under a specific circumference where the electron density is high and the electron temperature is low, compared to other plasma sources (e.g., inductively coupled plasma (ICP) or capacitively coupled plasma (CCP)). In the plasma in such a state, generation of more active species (radicals) and low energy ions is enabled so that a plasma doping treatment mainly by radicals and low energy ion components is enabled.

In addition, when a microwave input power is intentionally lowered, and a draw-in electric field is intentionally imparted to a to-be-processed sample (wafer) by strongly applying RF bias to a holding table of the to-be-processed sample (wafer), atoms in ionic plasma are irradiated strongly to the to-be-processed sample (wafer) so that a plasma doping treatment is implemented mainly by ions. For example, when RF bias of 13.56 MHz is applied at 500 W or more/(300 mm wafer stage)=7 mW/cm² or more, a plasma doping treatment mainly is implemented by ions. On this basis, it is desirable not to intentionally give a draw-in electric field to a to-be-processed substrate by strongly applying RF bias. For example, it is desirable not to apply RF bias of 13.56 MHz at 500 W or more/(300 mm wafer stage)=7 mW/cm² or more.

Further, the treatment condition of the plasma doping is set depending on a type of a dopant or a to-be-processed substrate. In the first exemplary embodiment, in order to dope a fin side in a high concentration, the AsH₃ flow rate is set to be large, and the pressure is set to be high. When the AsH₃ flow rate is set to be large and the pressure is set to be high, ion components are reduced so that a thick arsenic oxide film containing high concentration arsenic may be formed mainly on the top surface of the fin. Meanwhile, an upper limit value for the pressure is about 5 Torr.

After the plasma doping treatment has been performed under the above-described treatment condition, a heat treatment (annealing treatment) is performed on the to-be-processed substrate W which has been subjected to the plasma doping treatment. This is an application of the two-step heat treatment method, for which a conformal doping effect is demonstrated, to the case where the conformal doping is required to a substrate sample to be doped which accompanies a three-dimensional structure with respect to a conventional Si substrate as described in Document 5.

The heat treatment is performed in two stages of an intermediate annealing and an activation annealing. The controller 28 heats the to-be-processed substrate W by controlling, for example, the heater 34a of the holding table 34 or the temperature adjustment mechanism 29.

First, the controller 28 performs the intermediate annealing (step S3). Here, the controller 28 performs the intermediate annealing at 300° C. or higher to 650° C. or lower.

Here, the annealing treatment performed on the to-be-processed substrate after the plasma doping treatment step may be performed within the apparatus performing the plasma doping treatment continuously after the end of the plasma doping treatment. However, the annealing treatment is not limited thereto. For example, the to-be-processed substrate may be temporarily carried out from the apparatus performing the plasma doping treatment, and the annealing treatment may be performed thereon by using a separate apparatus. The annealing treatment may be performed by using, for example, rapid thermal annealing (RTA) or microwave annealing known in the related art.

The intermediate annealing is mainly aimed to volatilize and remove a compound containing a dopant excessively deposited on the to-be-processed substrate immediately after the plasma doping. Meanwhile, the intermediate annealing may be allowed to also perform an activation treatment of the dopant in the germanium substrate.

Next, an activation annealing is performed to the to-be-processed substrate W which has been subjected to the intermediate annealing (step S4). The activation annealing is aimed to activate a doped impurity. The activation annealing corresponds to performing an ultra-temperature and ultra-short-time heat treatment such as, for example, a spike annealing or a flash annealing, separately from the intermediate annealing. The controller 28 performs the activation annealing at a temperature in a range of, for example, about 650° C. to 800° C.

After the annealing treatment is finished, the to-be-processed substrate W is separated from the holding table 34 and carried out to the outside of the processing container 32.

(Effect in First Exemplary Embodiment-Suppression of Physical Damage)

Here, descriptions will be made on benefits obtained from using microwave plasma which is generated by using a radial line slot antenna, for a germanium- or Groups III-V-containing to-be-processed substrate which is easily damaged and suffers from surface roughness in a conventional treatment. As an example, a comparison will be made between the case where a treatment is performed using microwave plasma generated by using a radial line slot antenna and the case where a treatment is performed using inductively coupled plasma as a common plasma source. Hereinafter, among the treatment conditions, an electron temperature, an electron density, and a required pressure environment will be described.

In the case of plasma generated by inductive coupling, the electron temperature becomes about 2.0 eV, regardless of the distance from the bottom surface of the dielectric window. This electron temperature level may damage a to-be-processed substrate at the time of a plasma treatment. On the contrary, in the case of microwave plasma generated by using a radial line slot antenna, the electron temperature becomes about 1.5 eV, regardless of a distance from the bottom surface of the dielectric window. This so-called low electron temperature enables a plasma treatment to be implemented without damaging a to-be-processed substrate at the time of the plasma treatment.

In addition, in the case of the plasma generated by inductive coupling, the electron density increases as the distance from the bottom surface of the dielectric window increases, becomes a peak when the distance is about 50 mm, and gradually decreases as the distance further increases. On the contrary, in the case of the microwave plasma generated by using a radial line slot antenna, the electron density gradually decreases as the distance from the bottom surface of the dielectric window increases. Thus, in the case of the microwave plasma generated by using a radial line slot antenna, a plasma treatment may be easily implemented by adjusting the distance from the dielectric window depending on desired treatment efficiency.

Further, in the case of the microwave plasma generated by using a radial line slot antenna, a treatment may be implemented at the electron temperature lower than the electron temperature of the plasma generated by inductive coupling, regardless of a magnitude of a supplied power. Meanwhile, with respect to the electron density, when a supplied power is set to be identical, the microwave plasma generated by using the radial line slot antenna may implement the higher electron density than that of the plasma generated by inductive coupling.

As described above, by using the microwave plasma generated by using the radial line slot antenna, doping may be performed in the state of the low electron temperature and the high electron density. Thus, a plasma damage to a to-be-processed substrate due to doping may be reduced, and low-concentration doping may be efficiently implemented.

In addition, by the microwaves using a radial line slot antenna, plasma may be generated under an environment of a wide range of a pressure from a low pressure to a high pressure. Thus, the plasma generation may not be restricted by a type of a diluent gas or a gas for plasma excitation, and doping may be performed after generating plasma in a state in which a doping gas is supplied into a processing container. Therefore, the in-plane uniformity of a dose amount in a to-be-processed substrate may be enhanced.

As described above, when plasma is generated by microwaves generated by using a radial line slot antenna, a plasma irradiation damage to a to-be-processed substrate may be reduced, compared to inductively coupled plasma which is a common plasma source.

Next, descriptions will be made on a physical damage occurring when plasma doping is performed on a germanium substrate, by using specific data. A physical damage which occurs when plasma doping is performed on a germanium substrate may be evaluated based on a spread of a dopant, i.e., a degree of diffusion of a dopant when a heat treatment is applied. This is an evaluation method which applies the principle that when a crystal defect damage is present, a diffusion coefficient Do increases by a tangent enhanced diffusion (TED) effect.

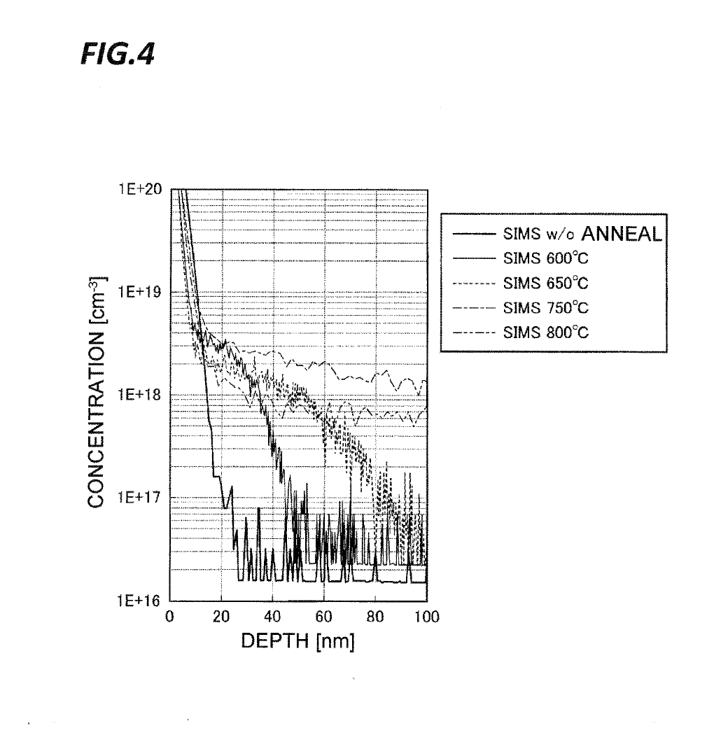

FIG. 4 is a view illustrating an exemplary SIMS profile obtained when arsenic is doped on a germanium substrate by using the semiconductor element manufacturing method according to the first exemplary embodiment. The example of FIG. 4 is an SIMS profile obtained in the case where arsenic is plasma-doped on a germanium substrate by using microwave plasma, and then, an RTA heat treatment (annealing treatment) is performed thereto. FIG. 4 represents a diffusion distance from the surface of the substrate in the horizontal axis, and a dopant concentration in the vertical axis.

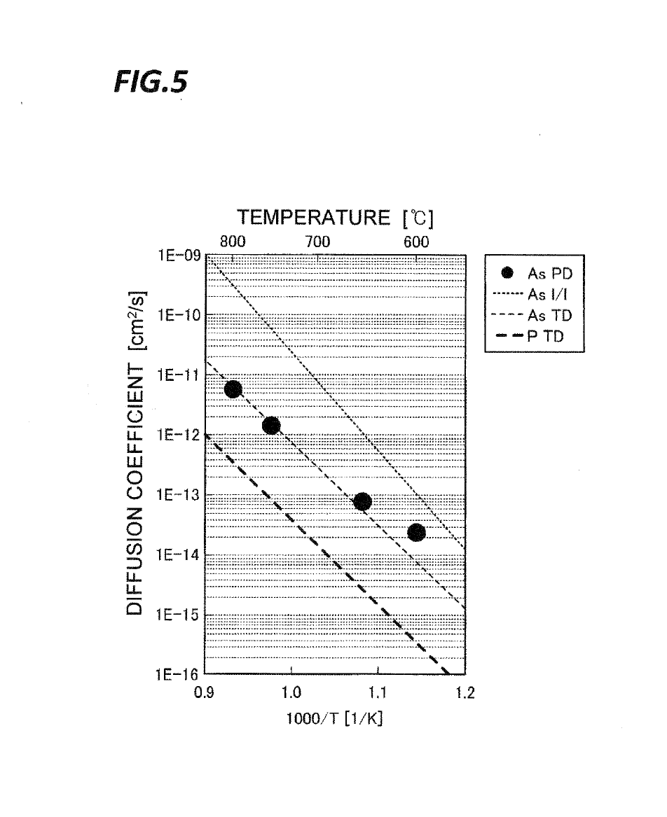

FIG. 5 is a view obtained by plotting a diffusion coefficient of a dopant with respect to an annealing temperature in the case of using the semiconductor element manufacturing method according to the first exemplary embodiment. It is known that when a crystal defect damage is present, a diffusion coefficient Do increases by the TED effect. FIG. 5 represents Do (four black circle plots) obtained by calculation from the experimental data (the SIMS profile) of the arsenic doping using microwave plasma as performed by the inventors of the present disclosure, and two straight lines as reference values which represent a relationship of a heat treatment temperature with respect to Do when an As doping layer is formed on an intrinsic Ge substrate through a thermal diffusion and Do when a P doping layer is formed on an intrinsic Ge substrate through a thermal diffusion (Non-Patent Document 7), and Do in a case of a beam ion implantation (Non-Patent Document 8).

A constant D₀ and active energy Ea are calculated by the following Equation 1:

D=D₀exp[−Ea/kT] [Equation 1]

In Equation 1, D₀ is a constant, Ea is active energy (eV), k is a Boltzmann's constant, and T is a temperature (K).

From this result, it can be understood that in the As doping using microwave plasma as performed by the inventors of the present disclosure, it is possible to perform doping which exhibits very small TED and is rather close to a thermal diffusion method of a solid impurity (solid source thermal diffusion) which dopes a solid dopant to a to-be-processed substrate by a thermal diffusion. Although clear from the plots of FIG. 5, when comparing the obtained Do value with that in the case of the beam ion implantation, the As doping using microwave plasma as performed by the inventors of the present disclosure exhibits Do=0.15 (cm²/s), and the beam ion implantation which is a comparison object exhibits Do=32 (cm²/s).

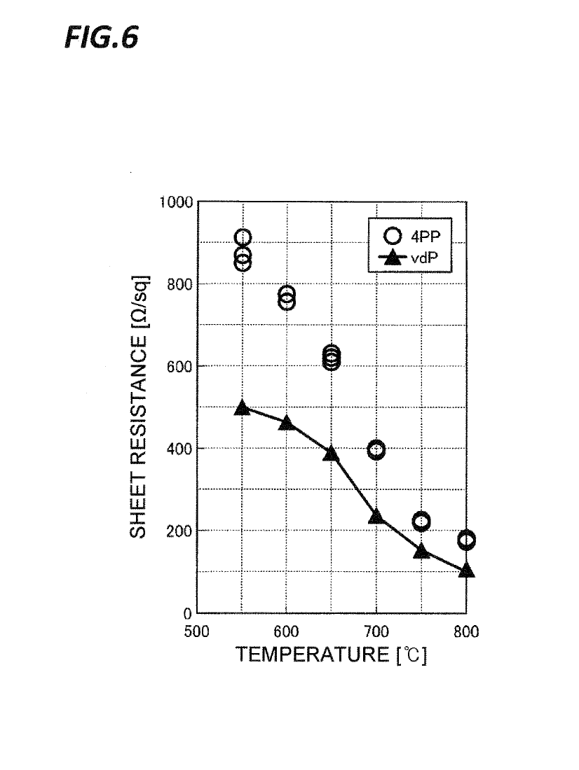

FIG. 6 is a view illustrating a result obtained by verifying a sheet resistance value for an annealing temperature through a 4-point probe method (4PP) and a Hall effect measurement method (vdP) in the case where an annealing treatment is performed by using the semiconductor element manufacturing method according to the first exemplary embodiment. Specifically, FIG. 6 illustrates a result obtained by verifying sheet resistance values for various annealing temperatures through the 4PP and the vdP in order to confirm whether an appropriate activation has been implemented in the case where an annealing treatment is performed for the As doping using microwave plasma as performed by the inventors of the present disclosure. From the result, since the germanium substrate exhibits no identical sheet resistance value in the 4PP and the vdP, but exhibits the sheet resistance which decreases with an increase of the temperature in both the 4PP and the vdP, it is believed that even when an annealing treatment is performed for the As doping using microwave plasma, an activation equivalent to the annealing temperature is implemented. Meanwhile, it is believed that no identical sheet resistance value is found in the 4PP and the vdP lies due to a measurement error.

As described above, even when plasma doping is performed on a germanium substrate by using a dopant having a large ion mass such as, for example, arsenic, the same diffusion coefficient as obtained when doping is performed by a thermal diffusion may be obtained. That is, by using plasma doping, the doping may be implemented while reducing a damage to a germanium substrate.

Meanwhile, of plasma doping, especially, plasma doping using surface wave plasma causes less damage to a to-be-processed substrate. As such, by using surface wave plasma, doping may be implemented with a less damage, even in the case of a material which easily suffers from surface roughness in a conventional ion implantation, such as for example, germanium.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of manufacturing a semiconductor element by implanting a dopant to a to-be-processed substrate, the method comprising:
a plasma doping treatment step of performing a plasma doping treatment on a to-be-processed substrate which contains germanium and is held on a holding table within a processing container, by generating high frequency plasma within the processing container by using microwaves.

2. The method of claim 1, wherein the plasma doping treatment step generates surface wave plasma as the high frequency plasma.

3. The method of claim 1, further comprising:
an annealing treatment step of performing an annealing treatment on the to-be-processed substrate which has been subjected to the plasma doping treatment.

4. The method of claim 3, wherein, in the annealing treatment step, an intermediate annealing treatment is performed, and then, an activation annealing treatment is performed so as to activate impurity within the to-be-processed substrate.

5. The method of claim 4, wherein the intermediate annealing treatment is performed at a temperature in a range of 300° C. to 650° C.

6. The method of claim 4, wherein the activation annealing treatment is performed at a temperature in a range of 650° C. to 800° C.
